(19) United States
(12) Patent Application Publication
(10) Pub. No.: US 2018/0340257 A1
(43) Pub. Date: Nov. 29, 2018

(54) DIFFUSER FOR UNIFORMITY IMPROVEMENT IN DISPLAY PECVD APPLICATIONS

(71) Applicant: Applied Materials, Inc., Santa Clara, CA (US)

(72) Inventors: Umesha ACHARY, Udupi District (IN); Sanjay D. YADAV, San Jose, CA (US); Lai ZHAO, Campbell, CA (US); Gaku FURUTA, Sunnyvale, CA (US); Ko-Ta SHIH, San Jose, CA (US); Soo Young CHOI, Fremont, CA (US)

(21) Appl. No.: 15/644,191

(22) Filed: Jul. 7, 2017

(30) Foreign Application Priority Data
May 25, 2017 (IN) 201741018368

(51) Int. Cl. C23C 16/50; C23C 16/458; C23C 16/455

(52) U.S. Cl. CPC C23C 16/50; C23C 16/455; C23C 16/458

(57) ABSTRACT

Embodiments described herein relate to a plasma enhanced chemical vapor deposition (PECVD) chamber and diffuser assembly for processing large area flat panel display substrates. The diffuser includes a first plate having a plurality of first bores formed therein, a second plate having a second plurality of bores formed therein, and a third plate having a third plurality of bores formed therein. The second plate is disposed between the first plate and the second plate. The first plate, second plate, and third plate are brazed to form a diffuser having a unitary body.

### CROSS-REFERENCE TO RELATED APPLICATIONS

This application claims benefit to Indian Provisional Patent Application No. 201741018368, filed May 25, 2017, the entirety of which is herein incorporated by reference.

### BACKGROUND

### Field

Embodiments of the present disclosure generally relate to a plasma enhanced chemical vapor deposition (PECVD) diffuser.

### Description of the Related Art

Flat panel displays are commonly used for active matrix displays such as computer and television monitors. PECVD is generally employed to deposit thin films on a substrate, such as a transparent substrate for flat panel display implementations. PECVD is generally accomplished by introducing a precursor gas or gas mixture into a vacuum chamber that contains a substrate. The precursor gas or gas mixture is typically directed toward the substrate through a distribution plate situated near a top of the chamber opposite the substrate. The precursor gas or gas mixture in the chamber is energized (e.g., excited) into a plasma by applying radio frequency (RF) power to the chamber from one or more RF sources coupled to the chamber. The excited gas or gas mixture reacts to form a layer of material on a surface of the substrate.

Flat panels processed by PECVD techniques are typically large, often exceeding several square meters. Gas distribution plates (or gas diffuser plates) utilized to provide uniform process gas flow over flat panels are relatively large in size, particularly as compared to gas distribution plates utilized for 200 mm and 300 mm semiconductor wafer processing. Further, as the substrates are rectangular, edges of the substrate, such as sides and corners thereof, experience conditions that may be different than the conditions experienced at other portions of the substrate. These different conditions affect processing parameters such as film thickness, deposition uniformity, and/or film stress.

As the size of substrates continues to grow in the flat panel display industry, film thickness and film uniformity control for large area PECVD becomes an issue. The difference of deposition rate and/or film property, such as film thickness or stress, between the center and the edges of the substrate becomes significant and may result in displays with suboptimal characteristics.

Therefore, what is needed in the art are improved gas distribution plate assemblies.

### SUMMARY

In one embodiment, a gas diffuser apparatus is provided. The apparatus includes a first plate having a first bore formed therein and a second plate having an orifice hole formed therein. The second plate is brazed to the first plate. The apparatus further includes a third plate having a second bore formed therein and the second plate is brazed to the third plate. A diameter of the orifice hole is less than a diameter of the first bore and a diameter of the second bore and the orifice hole is substantially aligned with a center of the first bore and a center of the second bore.

In another embodiment, a substrate process apparatus is provided. The apparatus includes chamber walls, a bottom coupled to the chamber walls, a backing plate coupled to the chamber walls opposite the bottom, and a diffuser coupled to the backing plate opposite the bottom. The diffuser includes a first plate having a first bore formed therein and a second plate having an orifice hole formed therein. The second plate is brazed to the first plate. The apparatus further includes a third plate having a second bore formed therein and the second plate is brazed to the third plate. A diameter of the orifice hole is less than a diameter of the first bore and a diameter of the second bore and the orifice hole is substantially aligned with a center of the first bore and a center of the second bore.

In yet another embodiment, a gas diffuser apparatus is provided. The apparatus includes a first aluminum plate having a first bore formed therein and a diameter of the first bore is constant alone a depth of the first bore. A second aluminum plate is brazed to the first aluminum plate, the second aluminum plate has an orifice hole formed therein, and a diameter of the orifice hole is constant along a depth of the orifice hole. A third aluminum plate is brazed to the second aluminum plate, the second aluminum plate has a second bore formed therein, and a diameter of the second bore increases along a depth of the second bore from a first surface of the third aluminum plate adjacent to the second aluminum plate to a second surface of the third aluminum plate opposite the first surface.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates a schematic, cross-sectional view of a PECVD chamber according to embodiments described herein.

FIG. 2 illustrates a schematic, cross-sectional view of a portion of a diffuser of FIG. 1 according to embodiments described herein.

FIG. 3 illustrates a schematic, cross-sectional view of a portion of a diffuser of FIG. 1 according to embodiments described herein.

FIG. 4 illustrates a schematic, cross-sectional view of a portion of a diffuser of FIG. 1 according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein relate to a PECVD chamber and diffuser assembly for processing large area flat panel display substrates. The diffuser includes a first plate having a plurality of first bores formed therein, a second plate having a second plurality of bores formed therein, and a third plate having a third plurality of bores formed therein. The second plate is disposed between the first plate and the second plate. The first plate, second plate, and third plate are brazed to form a diffuser having a unitary body.

Embodiments described herein provide for a diffuser assembly which enables substantially uniform deposition on a substrate. In operation, the diffuser assembly can compensate for non-uniformities corresponding to various regions of the substrate. According to embodiments described herein, the diffuser assembly compensates for the non-uniformities by adjusting flow of gases through the plates comprising the diffuser assembly in areas where deposition is non-uniform. In one embodiment, a local gas flow gradient within one or more portions of the diffuser assembly may be modulated to provide a greater flow rate though portions of the diffuser assembly relative to other portions of the diffuser assembly in order to compensate for non-uniformities. In one aspect, an orifice of a gas passage can be sized to improve maintenance of plasma generation through the diffuser assembly. The orifice size can be varied to form a gradient of orifice diameters or a mixture of diameters that result in substantially uniform deposition.

Embodiments herein are illustratively described below in reference to a PECVD system configured to process large area substrates, such as a PECVD system, available from AKT, a division of Applied Materials, Inc., Santa Clara, Calif. It is contemplated that other suitably configured apparatus from other manufacturers may also be implemented according to the embodiments described herein. In addition, it should be understood that various implementations described herein have utility in other system configurations, such as etch systems, other chemical vapor deposition systems, or other systems in which distributing gas within a process chamber is desired, including those systems configured to process round substrates.

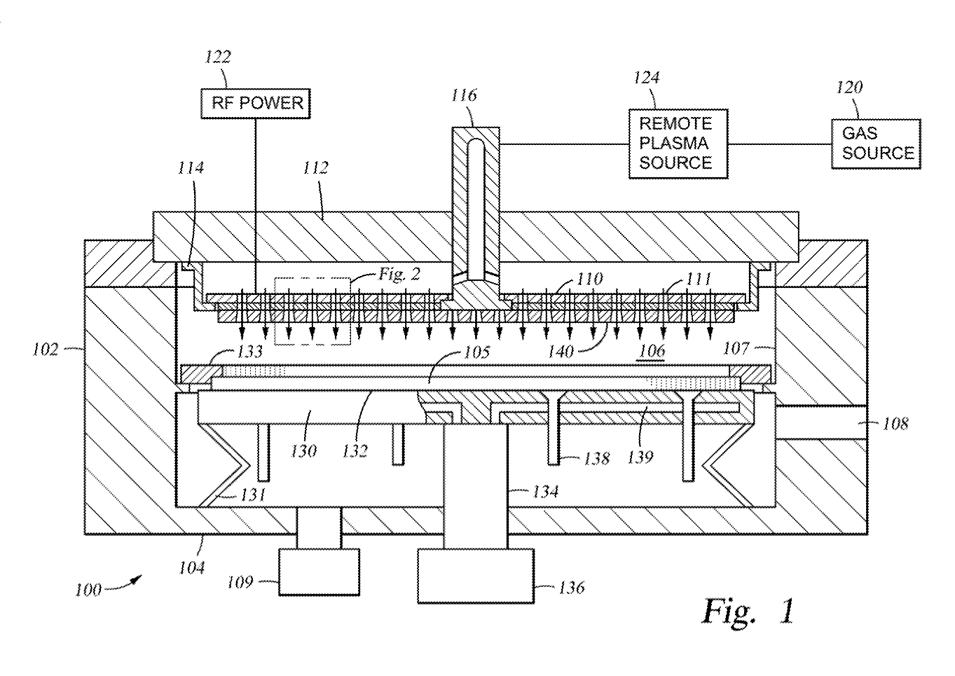

FIG. 1 illustrates a schematic, cross-sectional view of a PECVD chamber 100 for forming electronic devices for flat panel displays, such as thin film transistor (TFT) devices and active matrix organic light emitting diode (AMOLED) devices. The chamber 100 includes walls 102, a bottom 104, and a diffuser 110 which define a process volume 106. More specifically, the process volume 106 is further defined by surfaces 107 of the walls 102. In one embodiment, the walls 102, bottom 104, and diffuser are fabricated from a metallic material, such as aluminum, stainless steel, and alloys thereof. For example, the diffuser 110 may be formed from a 6061 aluminum alloy. In another embodiment, the diffuser 110 may be formed from an anodized aluminum material. A substrate support 130 is disposed in the process volume 106 opposite the diffuser 110. The process volume 106 is accessed through a sealable slit valve 108 formed through the walls 102 such that a substrate 105 may be transferred in and out of the chamber 100.

The substrate support 130 includes a substrate receiving surface 132 for supporting a substrate 105 and a stem 134 coupled to a lift system 136 to raise and lower the substrate support 130. In operation, a shadow frame 133 may be positioned over a periphery of the substrate 105 during processing. Lift pins 138 are moveably disposed through the substrate support 130 to move the substrate 105 to and from the substrate receiving surface 132 to facilitate substrate transfer. The substrate support 130 may also include heating and/or cooling elements 139 to maintain the substrate support 130 and substrate 105 positioned thereon at a desired temperature. The substrate support 130 may also include grounding straps 131 to provide RF grounding at a periphery of the substrate support 130.

The diffuser 110 is coupled to a backing plate 112 adjacent a periphery of the diffuser 110 by a suspension element 114. The diffuser 110 may also be coupled to the backing plate 112 by one or more center supports 116 to help prevent sag and/or control the straightness/curvature of the diffuser 110. A gas source 120 is fluidly coupled to the backing plate 112 to provide gas through the backing plate 112 to a plurality of gas passages 111 formed in the diffuser 110 and ultimately to the substrate receiving surface 132.

A vacuum pump 109 is coupled to the chamber 100 to control the pressure within the process volume 106. An RF power source 122 is coupled to the backing plate 112 and/or to the diffuser 110 to provide RF power to the diffuser 110 to generate an electric field between the diffuser 110 and the substrate support 130. In operation, gases present between the diffuser 110 and the substrate support 130 are energized by the RF electric field into a plasma. Various RF frequencies may be used, such as a frequency between about 0.3 MHz and about 200 MHz. In one embodiment, the RF power source 122 provides power to the diffuser 110 at a frequency of 13.56 MHz.

A remote plasma source 124 is also coupled between the gas source 120 and the backing plate 112. The remote plasma source 124 may be an inductively coupled remote plasma source, a capacitively coupled remote plasma source, or a microwave remote plasma source, depending upon the desired implementation. The remote plasma source 124 may be utilized to assist in process gas plasma generation and/or cleaning gas plasma generation.

In one embodiment, the heating and/or cooling elements 139 embedded in the substrate support 130 are utilized to maintain the temperature of the substrate support 130 and substrate 105 thereon during deposition of less than about 400 degrees Celsius or less. In one embodiment, the heating and/or cooling elements 139 are used to control the substrate temperature to less than 100 degrees Celsius, such as between 20 degrees Celsius and about 90 degrees Celsius.

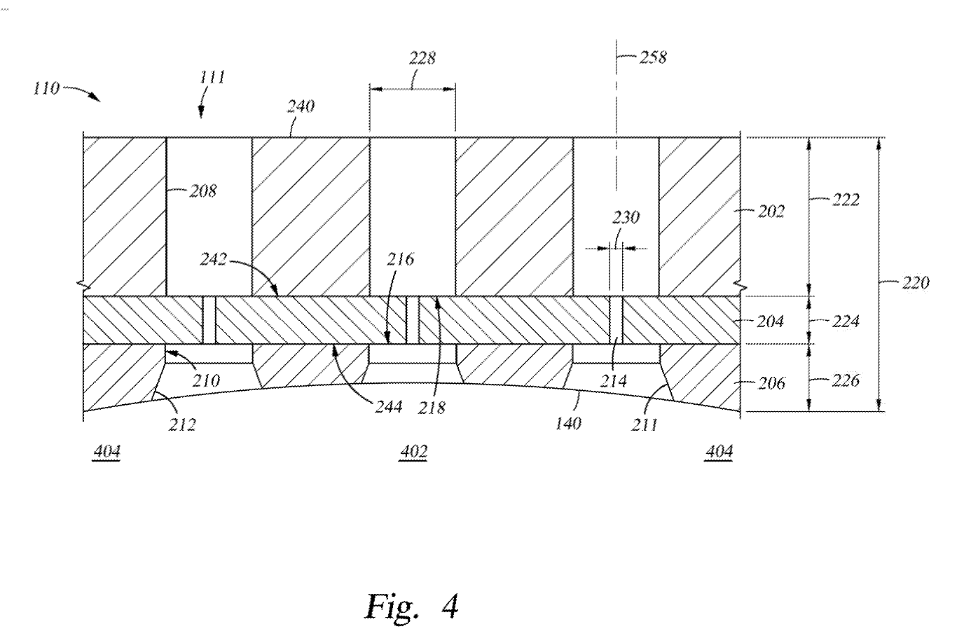

Spacing between a top surface of the substrate 105 disposed on the substrate receiving surface 132 and a bottom surface 140 of the diffuser 110 during deposition processes may be between 400 mil and about 1,200 mil, for example between 400 mil and about 800 mil. In one embodiment, the bottom surface 140 of the diffuser 110 may include a concave curvature wherein the center region is thinner than a peripheral region thereof (See FIG. 4). Alternatively, the bottom surface 140 may be substantially flat with no curvature. The chamber 100 may be used to deposit various materials, such as, silicon nitride material, silicon oxide material, amorphous silicon materials, for a variety of applications, including interlayer dielectric films and gate insulator films, among others.

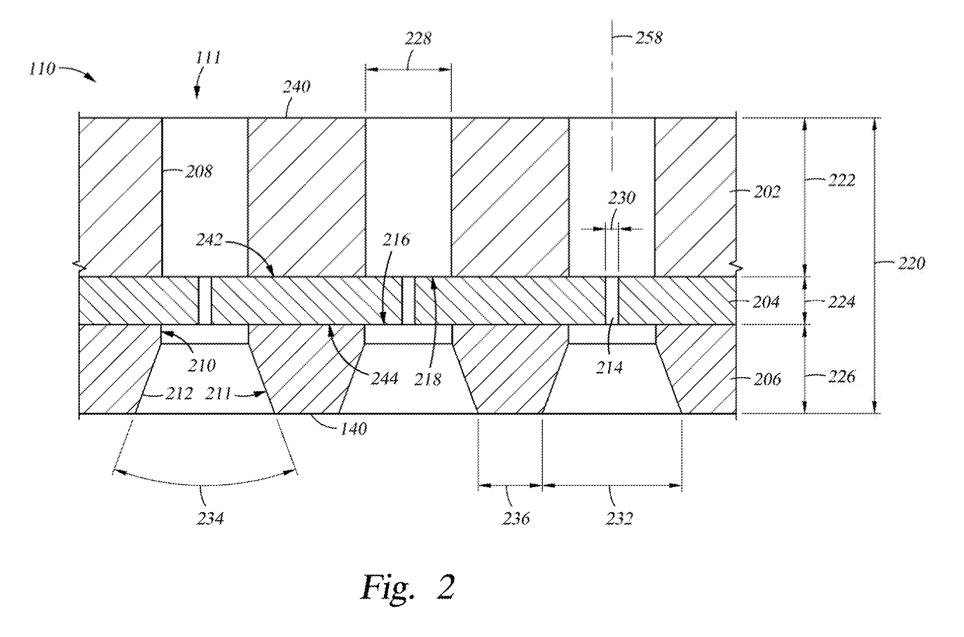

FIG. 2 illustrates a schematic, cross-sectional view of a portion of the diffuser 110 of FIG. 1 according to embodiments described herein. The diffuser 110 includes a first plate 202, a second plate 204, and a third plate 206. The first plate 202 has a first surface 240 which faces the backing plate 112 (shown in FIG. 1) and a second surface 242 which faces the second plate 204. In one embodiment, the second surface 242 is parallel to and opposite the first surface 240. The second plate 204 has a first surface 218 which is coupled to the second surface 242 of the first plate 202 and a second surface 216 which is coupled to a first surface 244 of the third plate 206. In one embodiment, the second surface 216 of the second plate 204 is parallel to and opposite the first surface 218 of the second plate 204. The third plate 206 also includes the bottom surface 140 which is disposed parallel to and opposite the first surface 244 of the third plate 206. The third plate 206 is also oriented such that the bottom surface 140 faces the substrate support 130 (shown in FIG. 1).

Each of the first plate 202 and the third plate 206 may be coupled to the second plate 204 such that the second plate 204 is disposed between the first plate 202 and the third plate 206. The first plate 202 and third plate 206 may be brazed to the second plate 204. For example, the first plate 202, the second plate 204, and the third plate 206 may be subjected to a vacuum brazing process to bond the three plates into a unitary body comprising the diffuser 110. A thickness 220 of the unitary body of the diffuser may be between about 0.50 inches and about 3.00 inches, such as between about 1.00 inch and about 2.00 inches, for example, about 1.20 inches. During the vacuum brazing process, a metallic foil material similar to or identical to the material utilized to form the first, second, and third plates, 202, 204, 206, respectively, is heated to near or above the melting point of the metallic material in order to braze the first plate 202 and the third plate 206 to the second plate 204.

Advantageously, the gas passages 111 formed in the first plate 202, the second plate 204, and the third plate 206 may be machined prior to brazing which improves efficiency of the machining process and the reliability with which the gas passages 111 are fabricated. Because the dimensions of the gas passages 111 influence gas flow distribution and various plasma characteristics and can be better controlled by machining the plates 202, 204, 206 separately, without a reduction in mechanical integrity of the diffuser 110 after brazing, improved film deposition uniformity may be achieved when processing substrates. In addition, cost reductions of diffuser fabrication may be realized according to the embodiments described herein.

Each of the gas passages 111 formed in the diffuser 110 are defined by a first bore 208 and a second bore 212 coupled together by an orifice hole 214. The first bore 208, the orifice hole 214, and the second bore 212 form a fluid path through the diffuser 110. The first bore 208 extends a first depth 222 from the first surface 240 of the first plate 202 to the second surface 242 of the first plate 202. The first depth 222 may extend between about 0.40 inches and about 1.20 inches, such as between about 0.60 inches and about 1.00 inch, for example, about 0.80 inches. In certain embodiments, the first depth 222 corresponds to a thickness of the first plate 202. The first bore 208 generally has a diameter 228 of between about 0.09 to about 0.22 inches, and in one embodiment, is about 0.15 inches.

The second bore 212 is formed in the third plate 206 of the diffuser 110 and extends a second depth 226 from the first surface 244 of the third plate 206 to the bottom surface 140 of the third plate 206. The second depth 226 may extend between about 0.10 inches and about 1.00 inch, such as between about 0.20 inches and about 0.40 inches, for example about 0.28 inches. A first region 210 of the second bore 212, which extends from the first surface 244 of the third plate toward the bottom surface 140, may have a diameter similar to the diameter 228 of the first bore 208. A second region 211 of the second bore 212 extends from the first region 210 to the bottom surface 140 of the third plate 206.

In one embodiment, a diameter of the second region 211 of the second bore 212 increases from the first region 210 to the bottom surface 140. In one embodiment, a diameter 232 of the second bore 212, measured where the second bore 212 intersects the bottom surface 140, is between about 0.10 inches and about 0.50 inches, such as between about 0.20 inches and about 0.30 inches, for example, about 0.24 inches. The second region 211 of the second bore 212 may also be flared at an angle 234 of between about 10 degrees and about 50 degrees relative to a hypothetical vertical axis. In one embodiment, the flaring angle 234 is between 15 degrees and about 30 degrees, such as between about 20 degrees and about 25 degrees, for example, about 22 degrees.

In one example, the diffuser 110 may be used to process 1500 mm by 1850 mm substrates and has second bores 212 at a diameter of about 0.24 inches and at a flare angle 234 of about 22 degrees. A distance 236 between adjacent second bores 212 is between about 0.0 inches to about 0.6 inch, and in one embodiment, is between about 0.01 inches and about 0.40 inches. The diameter 228 of the first bore 208 is usually, but not limited to, at least equal to or smaller than the diameter 232 of the second bore 212. The second regions 211 of the second bore 212 may be tapered, beveled, chamfered or rounded to minimize the pressure loss of gases flowing out from the orifice hole 214 and into the second bore 212.

The orifice hole 214, which is formed in the second plate 204, fluidly couples the first bore 208 to the second bore 212. In one embodiment, the orifice hole 214 is substantially aligned with a center 238 of the first bore 208 and the center 238 of the second bore 212. The orifice hole 214 has a diameter 230 of between about 0.001 inches and about 0.05 inches, such as between about 0.010 inches and about 0.030 inches, for example, about 0.018 inches. The orifice hole 214 extends a third depth 224 from the first surface 218 of the second plate 204 to the second surface 216 of the second plate 204. The third depth 224 may extend between about 0.01 inches and about 0.50 inches, such as between about 0.05 inches and about 0.20 inches, for example, about 0.10 inches. In certain embodiments, the third depth 224 of the orifice hole 214 corresponds to a thickness of the second plate 204.

The third depth 224 and diameter 230 (or other geometric attribute) of the orifice hole 214 is the primary source of back pressure in the volume between the diffuser 110 and the backing plate 112 (shown in FIG. 1) which promotes even distribution of gas across the first surface 240 of the first plate 202 of the diffuser 110. The orifice hole 214 is typically configured uniformly among the plurality of gas passages 111; however, the restriction through the orifice hole 214 may be configured differently among the gas passages 111 to promote more gas flow through one area or region of the diffuser 110 relative to another area or region. For example, the orifice hole 214 may have a larger diameter and/or a shorter depth in those gas passages 111, of the diffuser 110, closer to the wall 102 (shown in FIG. 1) of the processing chamber 100 so that more gas flows through the edges of the diffuser 110 to increase the deposition rate at portions of the perimeter areas of the substrate 105.

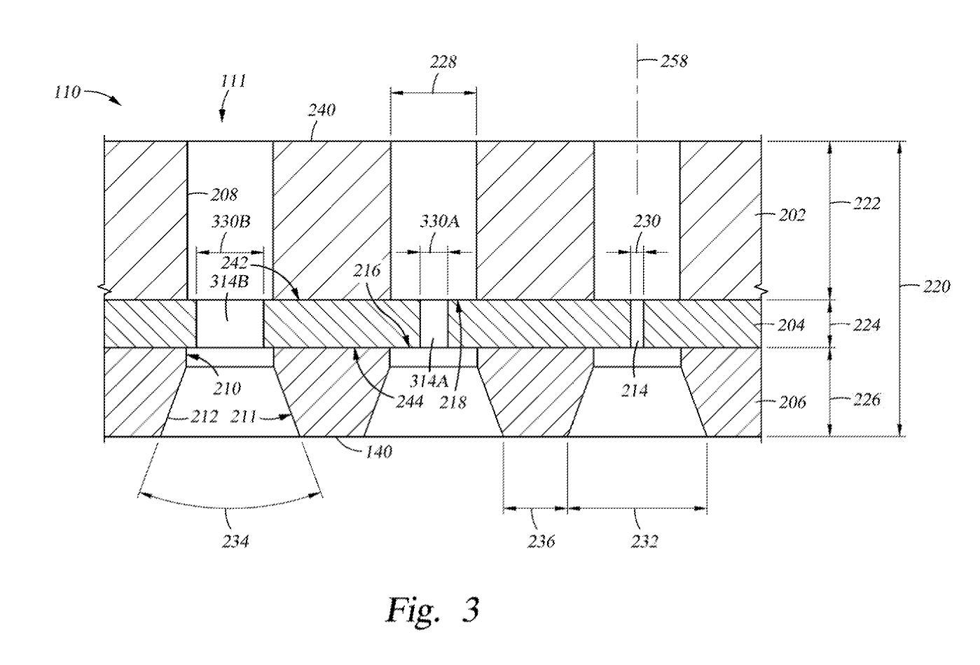

FIG. 3 illustrates a schematic, cross sectional view of the diffuser 110 of FIG. 1 according to one embodiment described herein. In the illustrated embodiment, the orifice holes 214 may have different diameters to generate unique localized flow gradients of gases when the gases pass through the orifice holes 214. For example, a localized gas flow gradient may be generated by one or more orifice holes 214, such as orifice hole 314A, having a first diameter 330A different than orifice holes 214, such as orifice hole 314B, having a second diameter 330B different than the first diameter 330A. In one embodiment, the first diameter 330A is greater than the second diameter 330B. In another embodiment, the first diameter 330A is less than the second diameter 330B. Additionally, the localized gas flow gradient may be enabled by utilizing orifice holes 214 having a first diameter interspersed within other or adjacent orifice holes 214 having a second diameter where the second diameter is different than the first diameter. In this manner, localized gas flow gradients may be achieved for different regions of the substrate 105, such as center regions and edge regions of the substrate 105.

FIG. 4 illustrates a schematic, cross-sectional view of a portion of the diffuser 110 according to another embodiments described herein. In the illustrated embodiment, the bottom surface 140 has a concave curvature. As such, the bottom surface 140 may have a curvilinear topography across peripheral regions 404 of the diffuser 110 and a center region 402 of the diffuser. In this embodiment, a thickness of the third plate 206 at the center region 402 is less than a thickness of the third plate 206 at the peripheral regions 404. Similarly, the third depth 224 of the second bore 212 at the center region is less than the third depth 224 of second bores 212 at the peripheral regions 404. It is contemplated that the third depth 224 for the second bores may not be constant for a single second bore 212, depending upon the curvature of the bottom surface 140. It is believed that utilizing the concave bottom surface 140 may further improve film deposition uniformity for large area substrates by compensating for center to edge variations in localized gas flow dynamics.

In summation, an improved diffuser is described herein which provides for improved manufacturing accuracy and efficiency. By more precisely controlling fabrication of the gas passages formed in the diffuser, fabrication cost reductions may be realized and improved deposition film uniformity results may be achieved.

While the foregoing is directed to embodiments of the present disclosure, other and further embodiments of the disclosure may be devised without departing from the basic scope thereof, and the scope thereof is determined by the claims that follow.

What is claimed is:

1. A gas diffuser apparatus, comprising:
a first plate having a first bore formed therein;
a second plate having an orifice hole formed therein, wherein the second plate is brazed to the first plate; and
a third plate having a second bore formed therein, wherein the second plate is brazed to the third plate, and wherein a diameter of the orifice hole is less than a diameter of the first bore and a diameter of the second bore and the orifice hole is substantially aligned with a center of the first bore and a center of the second bore.

2. The apparatus of claim 1, wherein the first plate, the second plate, and the third plate are formed from the same metallic material.

3. The apparatus of claim 2, wherein the metallic material is an aluminum alloy material.

4. The apparatus of claim 1, wherein the first bore has a constant diameter extending from a first surface of the first plate to a second surface of the first plate.

5. The apparatus of claim 1, wherein the orifice hole has a constant diameter extending from a first surface of the second plate to a second surface of the second plate.

6. The apparatus of claim 1, wherein the second bore has a first region having a diameter similar to a diameter of the first bore.

7. The apparatus of claim 6, wherein the second bore has a second region having a diameter greater than the diameter of the first region of the second bore.

8. The apparatus of claim 1, wherein a thickness of the first plate is between about 0.40 inches and about 1.20 inches.

9. The apparatus of claim 8, wherein a depth of the first bore corresponds to the thickness of the first plate.

10. The apparatus of claim 1, wherein the orifice hole has a depth between about 0.01 inches and about 0.50 inches.

11. The apparatus of claim 10, wherein a thickness of the second plate corresponds to the depth of the orifice hole.

12. The apparatus of claim 1, wherein a diameter of the orifice hole is between about 0.001 inches and about 0.100 inches.

13. The apparatus of claim 1, wherein the first plate, the second plate, and the third plate form a unitary body having a continuous gas passage formed therethrough.

14. The apparatus of claim 13, wherein the continuous gas passage comprises:
the first bore;
the orifice hole; and
the second bore.

15. A substrate process apparatus, comprising:
chamber walls;
a bottom coupled to the chamber walls;
a backing plate coupled to the chamber walls opposite the bottom;
a diffuser coupled to the backing plate opposite the bottom, wherein the diffuser comprises:
a first plate having a first bore formed therein;
a second plate having an orifice hole formed therein, wherein the second plate is brazed to the first plate; and
a third plate having a second bore formed therein, wherein the second plate is brazed to the third plate, and wherein a diameter of the orifice hole is less than a diameter of the first bore and a diameter of the second bore and the orifice hole is substantially aligned with a center of the first bore and a center of the second bore.

16. The apparatus of claim 15, further comprising:
a substrate support disposed in the substrate process apparatus opposite the diffuser.

17. The apparatus of claim 15, further comprising:
a remote plasma source in fluid communication with the diffuser.

18. A gas diffuser apparatus, comprising:
a first aluminum plate having a first bore formed therein, wherein a diameter of the first bore is constant along a depth of the first bore;
a second aluminum plate brazed to the first aluminum plate, the second aluminum plate having an orifice hole formed therein, wherein a diameter of the orifice hole is constant along a depth of the orifice hole; and
a third aluminum plate brazed to the second aluminum plate, the second aluminum plate having a second bore formed therein, wherein a diameter of the second bore increases along a depth of the second bore from a first surface of the third aluminum plate adjacent to the second aluminum plate to a second surface of the third aluminum plate opposite the first surface.

19. The apparatus of claim 18, wherein the diameter of the first bore is equal to or less than the diameter of the second bore.

20. The apparatus of claim 18, wherein a portion of the second bore is flared at an angle of between about 20 degrees and about 25 degrees.
